(19) United States
(12) Patent Application Publication
(10) Pub. No.: US 2017/0335180 A1
(43) Pub. Date: Nov. 23, 2017

(54) SEMICONDUCTOR NANOCRYSTAL-SILOXANE COMPOSITE RESIN COMPOSITION AND PREPARATION METHOD THEREOF

(71) Applicant: KOREA ADVANCED INSTITUTE OF SCIENCE AND TECHNOLOGY, Daejeon (KR)

(72) Inventors: Byeong-Soo BAE, Daejeon (KR); Hwea Yoon KIM, Daejeon (KR); Gwang-Mun CHOI, Daejeon (KR)

(21) Appl. No.: 15/597,832

(22) Filed: May 17, 2017

(30) Foreign Application Priority Data
May 18, 2016 (KR) 10-2016-0061019

(51) Int. Cl. C09K 11/02; C08G 77/06; C08G 77/14; C09K 11/56; H01L 33/56; H01L 33/50; C09K 11/54; B82Y 40/00; B82Y 20/00; C08G 77/00

(52) U.S. Cl. CPC C09K 11/025; H01L 33/502; C08G 77/06; C08G 77/14; C09K 11/54; C09K 11/565; H01L 33/56; B82Y 20/00; C08G 77/80; B82Y 40/00; H01L 2933/0083; Y10S 977/774; Y10S 977/824; Y10S 977/892; Y10S 977/95

(57) ABSTRACT

The present invention relates to a semiconductor nanocrystal-siloxane composite resin composition and a preparation method thereof, and more specifically to a semiconductor nanocrystal-siloxane composite resin composition in which semiconductor nanocrystals are dispersed and bonded to a siloxane composite resin obtained by condensation reaction of a mixture of one or more organoalkoxysilanes or organosilanediol, and a preparation method thereof. The cured product of the semiconductor nanocrystal-siloxane resin composition of the present invention can be prepared as a coating, a film, a flake, etc., and the inherent characteristics of the semiconductor nanocrystal are maintained in a high temperature and high humidity environment and the reliability of the application devices is improved.

### CROSS-REFERENCE TO RELATED APPLICATION

This application claims priority under 35 U.S.C. §119 to Korean Patent Application No. 10-2016-0061019, filed in the Korean Intellectual Property Office on May 18, 2016, the disclosure of which is incorporated by reference herein in its entirety.

### TECHNICAL FIELD

The present invention relates to a semiconductor nanocrystal-siloxane composite resin composition which can maintain the inherent properties of the semiconductor nanocrystal by improving the fluorescence stability at a high temperature and high humidity environment, and can also be applied to various devices by improvement of the reliability.

### BACKGROUND ART

Semiconductor nanocrystals, which are also called quantum dots, are composed of hundreds to thousands of atoms. Therefore, the semiconductor nanocrystals have a large surface area per unit volume and exhibit different physical characteristics from those of bulk semiconductor due to the quantum confinement effect. The properties of the semiconductor nanocrystals can be varied by changing size of the semiconductor nanocrystals, and due to the excellent physical, chemical and electrical properties, research and development for applying them to various optical devices are actively being carried out.

In order to apply the semiconductor nanocrystals to various optical devices, it is a common method to disperse the semiconductor nanocrystals in a polymer resin or the like to flake it for use. In general, acryl-based or siloxane-based resins having excellent transparency are used as the polymer resin used for flaking of semiconductor nanocrystals. Among the siloxane-based resins, the PDMS resin whose main chain has a siloxane structure is more stable to heat and ultraviolet region than the hydrocarbon-based resin whose main chain is composed of carbon, and thus is useful for application to optical materials. However, when the semiconductor nanocrystals are dispersed in the polymer resin, the high surface energy of the semiconductor nanocrystals is not compatible with the hydrocarbon-based ligand used in synthesizing the semiconductor nanocrystals, and thus agglomeration easily occurs, and dispersion is impossible without exchanging a ligand of the semiconductor nanocrystal surface or adding a dispersant. Further, even when the ligand is exchanged or the dispersant is added, the long-term storage stability is weak. In addition, semiconductor nanocrystals composed of a metal are very vulnerable to heat and moisture, and are easily oxidized to lose their inherent properties.

Previous studies have been conducted to solve the dispersion of the semiconductor nanocrystal in the polymer resin and the problem of being vulnerable to heat and moisture.

For example, in order to disperse a semiconductor nanocrystal in a siloxane-based polymer resin, a method of exchanging a conventional ligand existing on the semiconductor nanocrystal surface with a siloxane series (Patent Documents 1 to 4), a method for encapsulating a semiconductor nanocrystal with a siloxane-based compound (Patent Document 5), and a method of adding a dispersant to siloxane-based and hydrocarbon-based resins (Patent Documents 6 to 7) have been proposed.

However, the methods proposed above still have the following problems.

First, in general, the method of exchanging ligands of the semiconductor nanocrystal surface or encapsulating or coating the surface allows a change the inherent characteristics of semiconductor nanocrystals, and particularly, the ligand exchange method most frequently used in the art causes a serious deterioration of quantum efficiency (Patent Documents 1 to 4). That is, according to Patent Documents 1 to 4, the ligand exchange on the semiconductor nanocrystal surface causes a significant decrease in important fluorescence properties of the semiconductor nanocrystal. Therefore, in order to maintain the characteristics of the semiconductor nanocrystal, it is necessary to use the semiconductor nanocrystals synthesized at the initial stage without a ligand exchange process.

Specifically, in order to disperse the semiconductor nanocrystal into a commercialized siloxane-based resin, Patent Documents 1 to 3 disclose a method of complexing with a commercialized siloxane resin in which the semiconductor nanocrystal surface ligand is exchanged with a ligand having a linear siloxane structure, thereby achieving uniform dispersion. Further, Patent Document 4 attempted to achieve uniform dispersion by exchanging the ligands of the semiconductor nanocrystal surface in order to disperse semiconductor nanocrystals into a commercialized siloxane and a hydrocarbon-based resin. However, the methods of Patent Documents 1 to 4 are limited to changing the ligand on the semiconductor nanocrystal surface in order to uniformly disperse the semiconductor nanocrystals in the existing commercial polymer resin, instead of developing a new polymer resin.

In addition, in Patent Document 5, in order to disperse semiconductor nanocrystals in a commercialized siloxane-based resin without exchanging a ligand of the semiconductor nanocrystal surface, a semiconductor nanocrystal was encapsulated with a commercialized linear siloxane-based compound to thereby prepare UV stabilized and heat resistant composite. However, the above Patent Document does not relate to the development of new polymer resins, the evaluation was carried out for only 240 hours which is less than ¼ of reliability test time (1000 hours) required in industry, and the reliability evaluation on humidity was not performed. Further, the luminous efficiency decreased by 14% during the evaluation time.

Second, in Patent Documents 6 and 7, a dispersant was added for dispersing semiconductor nanocrystals in the polymer resin. However, the addition of the dispersant may make the stability of the semiconductor nanocrystal polymer composite fragile at the time of raising the temperature, thereby causing deterioration of the properties of the semiconductor nanocrystal in the composite.

Therefore, without exchanging the organic ligand of the semiconductor nanocrystal and adding the dispersant, uniform dispersion of the semiconductor nanocrystal can be achieved without aggregation in the siloxane-based polymer resin. Further, in order to improve the reliability of the application devices, it is required to develop a new semiconductor nanocrystal polymer composite resin capable of effectively protecting semiconductor nanocrystals from the heat or moisture external environment.

### PRIOR ART DOCUMENTS

### Patent Documents

(Patent Document 1) [Document 1] International Application No. PCT/US2010/001283
(Patent Document 2) [Document 2] International Application No. PCT/US2013/045244
(Patent Document 3) [Document 3] International Application No. PCT/162013/059577
(Patent Document 4) [Document 4] International Application No. PCT/US2011/000724
(Patent Document 5) [Document 5] Korean Patent Laid-Open Publication No. 10-2014-0006310
(Patent Document 6) [Reference 6] Korean Patent No. 10-1249078
(Patent Document 7) [Reference 7] Korean Patent Laid-Open Publication No. 10-2015-0041581

### Non-Patent Document

(Non-Patent Document 1)[Reference 1] KIM, Sungjee; BAWENDI, Moungi G. Oligomeric ligands for luminescent and stable nanocrystal quantum dots. Journal of the American Chemical Society, 2003, 125.48: 14652-14653.
(Non-Patent Document 2)[Reference 2] WANG, Xiao-Song, et al. Surface passivation of luminescent colloidal quantum dots with poly (dimethylaminoethyl methacrylate) through a ligand exchange process. Journal of the American Chemical Society, 2004, 126.25: 7784-7785.
(Non-Patent Document 3)[Reference 3] DUBOIS, Fabien, et al. A versatile strategy for quantum dot ligand exchange. Journal of the American Chemical Society, 2007, 129.3: 482-483.
(Non-Patent Document 4)[Reference 4] PONG, Boon-Kin; TROUT, Bernhardt L.; LEE, Jim-Yang. Modified ligand-exchange for efficient solubilization of CdSe/ZnS quantum dots in water: A procedure guided by computational studies. Langmuir, 2008, 24.10: 5270-5276.

### DETAILED DESCRIPTION OF THE INVENTION

### Technical Problem

In order to solve the aforementioned problems of the prior arts, it is an object of the present invention to provide a semiconductor nanocrystal-siloxane composite resin composition capable of achieving uniform dispersion without ligand exchange of a semiconductor nanocrystal surface in a siloxane resin having a dense inorganic network structure, and a method for preparing the same.

It is another object of the present invention to provide a cured product of a semiconductor nanocrystal-siloxane composite in which the cured product is prepared through ultraviolet curing and/or heat curing of the resin composition, whereby the semiconductor nanocrystals in the siloxane network structure are stably encapsulated by the siloxane structure, and protected from external environment, thereby securing excellent reliability, and a device using the same.

### Technical Solution

In order to achieve the above objects, the present invention provides a semiconductor nanocrystal-siloxane composite resin composition comprising a composite resin in which the surface of the semiconductor nanocrystal is encapsulated by being dispersed and bound by a siloxane composite resin having a network structure,

wherein the siloxane composite resin having a network structure includes a hydrolytic or non-hydrolytic condensation reaction product derived from at least one silane-based compound selected from the group consisting of an organoalkoxysilane and organosilanediol comprising semiconductor nanocrystals.

Preferably, the present invention provides a semiconductor nanocrystal-siloxane composite resin composition comprising a composite resin in which the surface of the semiconductor nanocrystal is encapsulated by being dispersed and bound by the siloxane composite resin having a network structure,

wherein the siloxane composite resin having a network structure encloses the semiconductor nanocrystal and includes a hydrolytic or non-hydrolytic condensation reaction product derived from at least one silane-based compound selected from the group consisting of an organoalkoxysilane and an organosilanediol.

The organoalkoxysilane can be selected from a compound represented by the following Chemical Formula 1 or a mixture of one or more thereof:

R¹ₙSi(OR²)₄₋ₙ [Chemical Formula 1]

in the above Chemical Formula 1,

each R¹ is independently a (C₁˜C₂₀) alkyl, a (C₃˜C₈) cycloalkyl, a (C₁˜C₂₀) alkyl substituted with a (C₃˜C₈) cycloalkyl, a (C₂˜C₂₀) alkenyl, a (C₂˜C₂₀) alkynyl or a (C₆˜C₂₀)aryl group, wherein the R₁ may have one or more functional groups selected from the group consisting of an acrylic group, a (meth)acryl group, an aryl group, a halogen group, an amino group, a mercapto group, an ether group, an epoxy group, a vinyl group, a hydrogen group, a methyl group, a phenyl group and an isocyanate group,

each R² is independently a linear or branched (C₁˜C₇) alkyl, and

n is an integer of 0 to 3.

The organoalkoxysilane may be one or more selected from the group consisting of tetraethoxysilane, tetramethoxysilane, N-(3-acryloxy-2-hydroxypropyl)-3-aminopropyltriethoxysilane, N-3-(acryloxy-2-hydroxypropyl)-3-aminopropyltrimethoxysilne, N-3-(acryloxy-2-hydroxypropyl)-3-aminopropyltripropoxysilne, 3-acryloxypropylmethylbis(trimethoxy)silane, 3-acryloxypropyltrimethoxysilane, 3-acryloxypropyltriethoxysilane, 3-acryloxypropyltripropoxysilane, 3-(meth)acryloxypropyltrimethoxysilane, 3-(meth)acryloxypropyltrimethoxysilane, 3-(meth)acryloxypropyltripropoxysilane, 2-(3,4-epoxycyclohexyl)ethyltrimethoxysilane, 2-(3,4-epoxycyclohexyl)ethyltriethoxysilane, vinyltrimethoxysilane, vinyltriethoxysilane, vinyltripropoxysilane, methyltrimethoxysilane, methyltriethoxysilane, methyldimethoxysilane, methyldiethoxysilane, phenyltrimethoxysilane, phenyltriethoxysilane, diphenyldimethoxysilane, diphenyldiethoxysilane, N-(aminoethyl-3-aminopropyl)trimethoxysilane, N-(2-aminoethyl-3-aminopropyl)triethoxysilane, 3-aminopropyltrimethoxysilane, 3-aminopropyltriethoxysilane, 3-isocyanatopropyltriethoxysilane, heptadecafluorodecyltrimethoxysilane, chloropropyltrimethoxysilane, and chloropropyltriethoxysilane.

The organosilanediol may be selected from a compound represented by the following Chemical Formula 2 or a mixture of one or more thereof:

R³ₘR⁴_{K}Si(OH)₄₋ₘ₋ₖ [Chemical Formula 2]

in the above Chemical Formula 2,

R³ and R⁴ are each independently or simultaneously a (C₁˜C₂₀) alkyl, a (C₃˜C₈) cycloalkyl, a (C₁˜C₂₀) alkyl substituted with a (C₃˜C₈) cycloalkyl, a (C₂˜C₂₀) alkenyl, a (C₂˜C₂₀) alkynyl or a (C₆˜C₂₀)aryl group, wherein the R³ and R⁴ may have one or more functional groups selected from the group consisting of an acrylic group, a methacryl group, an aryl group, a halogen group, an amino group, a mercapto group, an ether group, a (C₁˜C₂₀) alkoxy group, a sulfone group, a nitro group, a hydroxy group, a cyclobutene group, a carbonyl group, a carboxyl group, an alkyd group, a urethane group, a vinyl group, a nitrile group, an epoxy group, an oxetane group and a phenyl group, and

m and k are each an integer of 0 to 3.

The organosilanediol is preferably selected from the group consisting of diphenylsilanediol, diisobutylsilanediol, and mixtures thereof.

The semiconductor nanocrystal has a metal-based core-shell structure and may include one or more ligands on the surface.

The siloxane composite resin composition may further contain a reactive monomer or oligomer having an epoxy group, an acrylic group or an oxetane group in an amount of 1 to 50 parts by weight based on 100 parts by weight of the total siloxane composite resin.

In addition, the present invention provides a method for preparing the above-described semiconductor nanocrystal-siloxane composite resin composition comprising the steps of: a) preparing a composition containing a semiconductor nanocrystal, and at least one silane-based compound selected from the group consisting of the organoalkoxysilane represented by the Chemical Formula 1 and the organosilanediol represented by the Chemical Formula 2; and

b) performing a condensation reaction of the composition containing the semiconductor nanocrystals and the silane-based compound while stirring to prepare a semiconductor nanocrystal-siloxane composite resin composition,

wherein the step b) includes a step of forming a siloxane resin having a network structure by a condensation reaction of the composition containing the semiconductor nanocrystal and the silane-based compound, and simultaneously dispersing the semiconductor nanocrystal in the siloxane resin and encapsulating the surface of the semiconductor nanocrystals with a siloxane resin.

Herein, the semiconductor nanocrystal may be used in an amount of 0.01 to 10 parts by weight based on 100 parts by weight of the total siloxane composite resin formed through a condensation reaction.

The condensation reaction in the step b) may include a hydrolytic condensation reaction or a non-hydrolytic condensation reaction.

The hydrolytic condensation reaction may include a hydrolytic condensation reaction of a mixture containing an organoalkoxysilane and water in a molar ratio of 1:0.5 to 4.

The non-hydrolytic condensation reaction may include a non-hydrolytic condensation reaction of a mixture containing an organoalkoxysilane and an organosilanediol in a molar ratio of 1:0.2 to 4.0.

The hydrolytic condensation reaction may include a hydrolytic condensation reaction of a mixture containing an organoalkoxysilane and water in a molar ratio of 1:0.5 to 5.

The non-hydrolytic condensation reaction may include a non-hydrolytic condensation reaction of a mixture containing an organoalkoxysilane and an organosilanediol in a molar ratio of 1:0.2 to 5.0.

After the step b), the method may further include the step of adding a curing catalyst to the semiconductor nanocrystal-siloxane composite resin composition.

Further, the method may further include the step of adding, to the semiconductor nanocrystal-siloxane composite resin composition of the step b), a reactive monomer or oligomer having an epoxy group, an acrylic group, or an oxetane group in an amount of 1 to 50 parts by weight based on 100 parts by weight of the entire siloxane composite resin.

Meanwhile, the present invention also provides a cured product of a semiconductor nanocrystal-siloxane composite resin composition including a cured product obtained through photocuring or heat curing of the above semiconductor nanocrystal siloxane composite resin composition.

Herein, the cured product may include films, flakes, sheets or encapsulated LED chips.

In addition, the present invention provides a device including a cured product of a semiconductor nanocrystal-siloxane composite.

### Advantageous Effects

The semiconductor nanocrystal-siloxane composite resin composition prepared according to the present invention can achieve uniform dispersion and encapsulation of semiconductor nanocrystals due to physicochemical interaction with a siloxane resin without exchanging organic ligands of semiconductor nanocrystals and without adding a dispersant. In particular, the cured product produced through the curing of the resin composition can realize high reliability having excellent heat and moisture stability because the siloxane of the network structure protects the semiconductor nanocrystals in the cured product from the external environment. Therefore, the present invention can broadly apply the composite resin to fields such as optics and displays by improving the reliability of application devices.

### BRIEF DESCRIPTION OF DRAWINGS

FIG. 1 shows a schematic reaction process for forming the semiconductor nanocrystal-siloxane composite resin of the present invention.

FIG. 2 is a schematic view showing the curing process of the semiconductor nanocrystal-siloxane composite resin obtained in FIG. 1 and the structure of the obtained cured product.

FIG. 3 shows the results of ²⁹Si-NMR spectrum analysis illustrating the structural characteristics of the semiconductor nanocrystal-siloxane resin of the present invention.

FIG. 4 shows the evaluation results of the dispersion stability of the semiconductor nanocrystal-siloxane composite resin composition of Comparative Example 1 and Example 1 of the present invention.

### DETAILED DESCRIPTION OF THE EMBODIMENTS

Hereinafter, the present invention will be described in more detail. In addition, since the present invention can be modified in various ways and can include various embodiments, specific embodiments thereof will be illustrated and described in detail below. However, this is not intended to limit the invention to the particular embodiments disclosed, and it should be understood to include all modifications, equivalents, and alternatives falling within the spirit and scope of the invention

Further, it will be understood that the terms “comprises” and/or “comprising” as used herein specify the presence of specific features, regions, integers, steps, operations, elements, and/or components, but do not preclude the presence or addition of one or more other features, regions, integers, steps, operations, elements, and/or components thereof.

Hereinafter, a preferred semiconductor nanocrystal-siloxane composite resin composition of the present invention and a method for preparing the same will be described in more detail.

Semiconductor Nanocrystal-Siloxane Composite Resin Composition

First, according to a preferred embodiment of the present invention, there is provided a semiconductor nanocrystal siloxane composite resin composition comprising a composite resin in which the surface of a semiconductor nanocrystal is encapsulated by being dispersed and bound by a siloxane composite resin having a network structure, wherein the siloxane complex resin having a network structure includes a hydrolytic or non-hydrolytic condensation reaction product derived from one or more silane compounds selected from the group consisting of an organoalkoxysilane and an organosilanediol.

That is, the present invention provides a semiconductor nanocrystal-siloxane composite resin and a cured product thereof in which the semiconductor nanocrystal is dispersed and bound to a siloxane composite resin which is synthesized by a condensation reaction of a mixture of at least one organoalkoxysilane or organosilanediol. In particular, in the case of the present invention, since at least one organoalkoxysilane or organosilanediol containing a semiconductor nanocrystal is used in the condensation reaction process for preparing a siloxane composite resin, a siloxane resin containing a matrix having an irregular network structure is produced and at the same time the semiconductor nanocrystal can be stably dispersed in the composite resin and encapsulated by the siloxane structure.

As described above, according to the present invention, since the semiconductor nanocrystal in the composite resin is encapsulated by the siloxane structure, it is stably protected from the external environment, thereby improving the reliability of the application device while maintaining the inherent characteristics of the semiconductor nanocrystal in the composite.

Herein, the semiconductor nanocrystal-siloxane composite resin composition of the present invention means that a semiconductor nanocrystal is encapsulated by a siloxane composite resin which is a state before being cured, and it is in a state of being dispersed in a siloxane composite resin. Moreover, the resin composition may contain a solvent. In addition, the cured product of the semiconductor nanocrystal siloxane composite means a state after the resin composition is subjected to an ultraviolet ray and/or a heat curing process, and it may be a composite resin.

The present invention will now be described in detail with reference to the drawings.

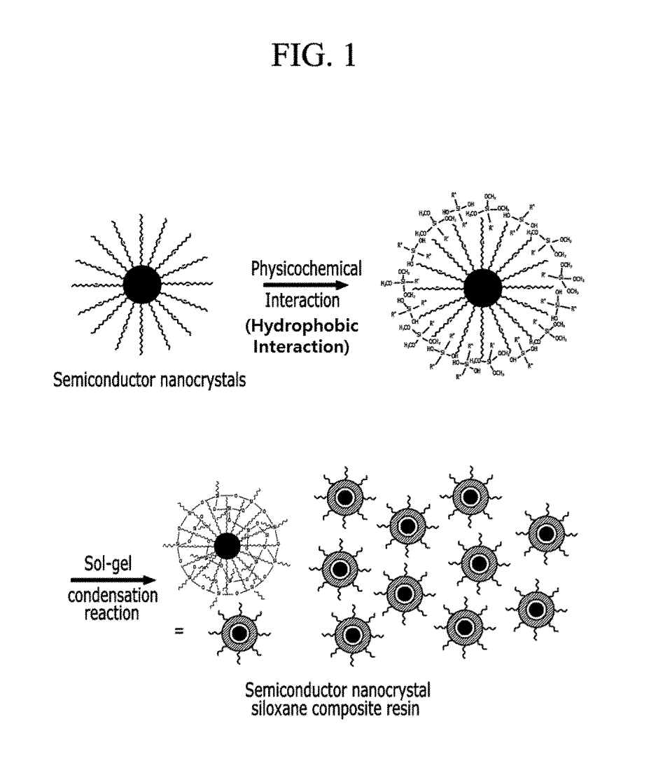

FIG. 1 shows a schematic reaction process for forming the semiconductor nanocrystal-siloxane composite resin of the present invention.

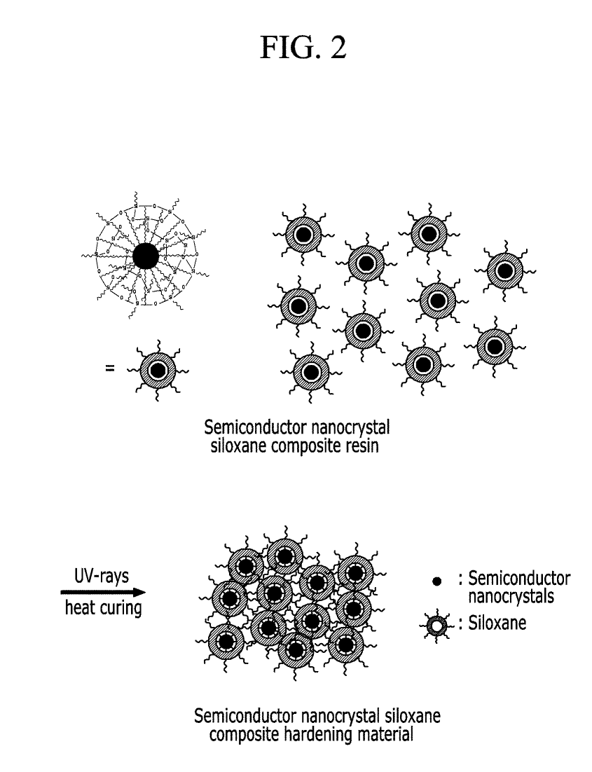

FIG. 2 is a schematic view showing the curing process of the semiconductor nanocrystal-siloxane composite resin obtained in FIG. 1 and the structure of the obtained cured product.

Specifically, the present invention binds the semiconductor nanocrystal and the siloxane composite resin through a physicochemical interaction (preferably a hydrophobic interaction). Herein, a process of subjecting the siloxane composite resin to a sol-gel condensation reaction for the hydrophobic interaction is performed, and the sol-gel condensation reaction is carried out while the semiconductor nanocrystals are present in the siloxane resin. Therefore, the functional groups of the siloxane resin can be easily interacted to the surface of the semiconductor nanocrystal, and the semiconductor nanocrystal can be dispersed in the siloxane composite resin. Therefore, as shown in FIG. 1, the semiconductor nanocrystal-siloxane composite resin can be prepared in such a manner that the semiconductor nanocrystals are dispersed in a siloxane composite resin synthesized by a hydrolytic or non-hydrolytic sol-gel condensation reaction of a mixture of at least one organalkoxysilane or organosilane diol.

Therefore, the resin prepared according to the method of the present invention is a resin in which the semiconductor nanocrystals are uniformly dispersed in the siloxane structure due to the physicochemical interaction (hydrophobic interaction) without exchanging the ligand of the semiconductor nanocrystal and adding a dispersant, and thus the aggregation phenomenon of the semiconductor nanocrystals does not occur for a long time.

In particular, the siloxane composite resin of the present invention does not contain only a linear structure as in the prior art, but includes an irregular network structure.

Specifically, in the above-described prior art Patent Document 1, the ligand of the semiconductor nanocrystal and the matrix material are manufactured using the same linear structure and chemical structure, and the matrix of the other prior art documents consists of hydrocarbon and siloxane resins having a commercialized linear structure.

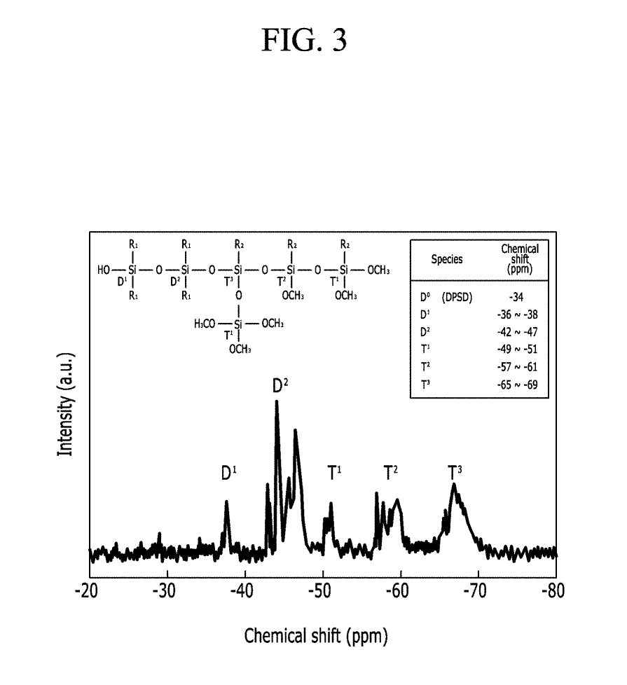

However, the siloxane resins of the present invention are characterized by providing a matrix having not only a linear structure but also an irregular siloxane network structure. Therefore, since the siloxane composite resin of the present invention includes both the regular linear structure and the irregular network structure, the semiconductor nanocrystals can be more uniformly dispersed in the resin than the prior art. For example, FIG. 3 shows the results of ²⁹Si-NMR spectrum analysis illustrating the structural characteristics of the semiconductor nanocrystal siloxane resin of the present invention. Referring to FIG. 3, it can be seen that the siloxane composite resin according to a preferred embodiment of the present invention forms a siloxane network structure (existence of T³ species).

Further, in the composition of the present invention, the semiconductor nanocrystals are dispersed in the siloxane composite resin having the network structure, and thus stable encapsulation is possible. In such a composite resin of the present invention, the network structure siloxane composite resin and the semiconductor nanocrystal encapsulated from the outside can be contained in a weight ratio of 1:0.0001 to 0.1.

In addition, the resin composition of the present invention may further include a curing catalyst.

The curing catalyst may be a catalyst used for subsequent ultraviolet ray curing and/or heat curing, the type thereof is not limited, and any type of curing catalyst may be used as long as it is generally used for curing a semiconductor nanocrystal composite resin.

Further, in the present invention, the siloxane composite resin composition may further contain 1 to 50 parts by weight of a reactive monomer or oligomer having an epoxy group, an acryl group, or an oxetane group based on 100 parts by weight of the entire siloxane composite resin.

By including the reactive monomer or oligomer, the viscosity, free volume, etc. of the final semiconductor nanocrystal-siloxane composite resin can be controlled and the processability can be facilitated. Examples of the reactive monomer or oligomer include 3-ethyl-3[[[3-ethyloxetan-3-yl]methoxy]methyl]oxetane, 1,6-hexanediol diacrylate, bisphenol A poly ethoxylate di(meth)acrylate, and the like.

In addition, the present invention can produce a cured product by performing ultraviolet curing and/or heat curing of a composition including the semiconductor nanocrystal siloxane composite resin having the structure of FIG. 1 (FIG. 2). In the case of the cured product thus produced, while maintaining a state in which the semiconductor nanocrystals in the structure are encapsulated by the siloxane structure, the bonding force between the siloxane composite resin and the semiconductor nanocrystals is excellent, and thus the semiconductor nanocrystals can be protected from the external environment. Therefore, the composite resin of the present invention exhibits excellent heat and moisture stability, so that reliability can be improved when applied to various devices.

Each component used for obtaining the siloxane composite resin in the present invention will be described as follows.

Among the silane-based compounds described above, the organoalkoxysilane can be selected from compounds represented by the following Chemical Formula 1 or a mixture of one or more thereof:

R¹ₙSi(OR²)₄₋ₙ [Chemical Formula 1]

wherein, in the above Chemical Formula 1,

each R¹ is independently a (C₁˜C₂₀)alkyl, a (C₃˜C₈)cycloalkyl, a (C₁˜C₂₀)alkyl substituted with a (C₃˜C₈)cycloalkyl, a (C₂˜C₂₀)alkenyl, a (C₂˜C₂₀)alkynyl, or a (C₆˜C₂₀)aryl group, wherein the R¹ may have one or more functional groups selected from an acrylic group, a (meth)acryl group, an aryl group, a halogen group, an amino group, a mercapto group, an ether group, an epoxy group, a vinyl group, a hydrogen group, a methyl group, a phenyl group and an isocyanate group,

each R² is independently a linear or branched (C₁˜C₇)alkyl, and

n is an integer of 0 to 3.

Therefore, as the above-mentioned organoalkoxysilane, any one or more of the following structural formulas can be used.

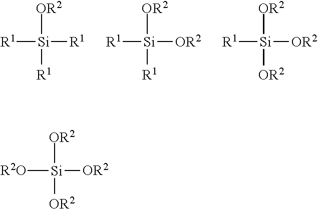

(in the above formulas, R¹ and R² are each as defined above)

More specifically, the organoalkoxysilane is at least one selected from the group consisting of tetraethoxysilane, tetramethoxysilane, N-(3-acryloxy-2-hydroxypropyl)-3-aminopropyltriethoxysilane, N-(3-acryloxy-2-hydroxypropyl)-3-aminopropyltrimethoxysilane, N-(3-acryloxy-2-hydroxypropyl)-3-aminopropyltripropoxysilane, 3-acryloxypropylmethylbis(trimethoxy)silane, 3-acryloxypropyltrimethoxysilane, 3-acryloxypropyltriethoxysilane, 3-acryloxypropyltripropoxysilane, 3-(meth)acryloxypropyltrimethoxysilane, 3-(meth)acryloxypropyltriethoxysilane, 3-(meth)acryloxypropyltripropoxysilane, 2-(3,4-epoxycyclohexyl)ethyltrimethoxysilane, 2-(3,4-epoxycyclohexyl)ethyltriethoxysilane, vinyltrimethoxysilane, vinyltriethoxysilane, vinyltripropoxysilane, methyltrimethoxysilane, methyltriethoxysilane, methyldimethoxy silane, methyl diethoxy silane, phenyl trimethoxy silane, phenyl triethoxy silane, diphenyl dimethoxy silane, diphenyl diethoxysilane, N-(aminoethyl-3-aminopropyl)trimethoxysilane, N-(2-aminoethyl-3-aminopropyl)triethoxysilane, 3-aminopropyltrimethoxysilane, 3-aminopropyltriethoxysilane, 3-isocyanatopropyltriethoxysilane, heptadecafluorodecyl trimethoxysilane, chloropropyl trimethoxysilane, chloropropyl triethoxysilane and the like, but is not limited thereto.

Among the silane-based compounds, the organosilanediol includes a silane-based compound containing two hydroxyl groups and an organic chain substituted or unsubstituted by a functional group. Preferably, it can be selected from the compound represented by the following Chemical Formula 2 or a mixture of at least one thereof.

R³ₘR⁴_{K}Si(OH)₄₋ₘ₋ₖ [Chemical Formula 2]

wherein, in the above Chemical Formula 2,

R³ and R⁴ are each independently or simultaneously a (C₁˜C₂₀)alkyl, a (C₃˜C₈)cycloalkyl, a (C₁˜C₂₀)alkyl substituted with a (C₃˜C₈)cycloalkyl, a (C₂˜C₂₀)alkenyl, a (C₂˜C₂₀)alkynyl, or a (C₈˜C₂₀)aryl group, wherein the R³ and R⁴ may have one or more functional groups selected from the group consisting of an acrylic group, a methacryl group, an aryl group, a halogen group, an amino group, a mercapto group, an ether group, a(C₁˜C₂₀)alkoxy group, a sulfone group, a nitro group, a hydroxyl group, a cyclobutene group, a carbonyl group, a carboxyl group, an alkyd group, a urethane group, a vinyl group, a nitrile group, an epoxy group, an oxetane group and a phenyl group, and

m and k are each an integer of 0 to 3.

More specifically, the organosilanediol may be selected from the group consisting of diphenylsilanediol, diisobutylsilanediol, and combinations thereof, but is not limited thereto.

The kind of the semiconductor nanocrystals in the semiconductor nanocrystal siloxane composite resin composition and the cured product thereof according to the present invention is not particularly limited and any of those well known in the art can be used.

For example, the semiconductor nanocrystals may be selected from the group consisting of a Group II-VI semiconductor compound, a Group II-V semiconductor compound, a Group III-VI semiconductor compound, a Group III-V semiconductor compound, a Group IV-VI semiconductor compound, a Group compound, a Group II-IV-VI compound, a Group II-IV-V compound, alloys thereof, and combinations thereof.

As the Group II element, Zn, Cd, Hg, or a combination thereof may be used. As the Group III element, Al, Ga, In, Ti, or a combination thereof may be used. As the Group IV element, Si, Ge, Sn, Pb, or a combination thereof may be used. As the Group V element, P, As, Sb, Bi or a combination thereof may be used, and as the Group VI element, O, S, Se, Te, or a combination thereof may be used.

The II-VI group semiconductor compound may be selected from the group consisting of a binary compound such as CdS, CdSe, CdTe, ZnS, ZnSe, ZnTe, ZnO, HgS, HgSe, HgTe and the like, a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe and the like, or a quaternary compound such as CdZnSeS, CdZnSeTe, CdZnSTe, CdHgSeS, CdHgSeTe, CdHgSTe, HgZnSeS, HgZnSeTe, HgZnSTe and the like. In addition, the III-V group semiconductor compound may be selected from the group consisting of a binary compound such as GaN, GaP, GaAs, GaSb, AlN, AlP, AlAs, AlSb, InN, InP, InAs, InSb and the like, a ternary compound such as GaNP, GaNAs, GaNSb, GaPAs, GaPSb, AlNP, AlNAs, AlNSb, AlPAs, AlPSb, InNP, InNAs, InNSb, InPAs, InPSb, GaAlNP, AlGaN, AlGaP, AlGaAs, AlGaSb, InGaN, InGaP, InGaAs, InGaSb, AlInN, AlInP, AlInAs, AlInSb and the like, or a quaternary compound such as GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb and the like. The IV-VI group semiconductor compound may be selected from the group consisting of a binary compound such as SnS, SnSe, SnTe, PbS, PbSe, PbTe and the like, or a ternary compound such as SnSeS, SnSeTe, SnSTe, PbSeS, PbSeTe, PbSTe, SnPbS, SnPbSe, SnPbTe and the like, or a quaternary compound such as SnPbSSe, SnPbSeTe, SnPbSTe and the like. The IV group semiconductor compound may be selected from the group consisting of a single-element compound such as Si, Ge and the like or a binary compound such as SiC, SiGe and the like.

The semiconductor nanocrystal may have a core-shell structure. The shell may include one or more layers. In addition, the shell may be composed of a Group II-VI semiconductor, a Group III-V semiconductor, a Group IV-VI semiconductor, or a combination thereof.

The semiconductor nanocrystal may include one or more ligands that are well known in the art.

Further, the semiconductor nanocrystals may have a multi-layer structure composed of two or more kinds of materials. Such a multi-layer structure may include an alloy interlayer of two or more materials at the interface between the layers, and the alloy layer may be a gradient alloy having a gradient of the material composition.

Method for Preparing Semiconductor Nanocrystal-Siloxane Composite Resin Composition

According to another preferred embodiment of the present invention, there is provided a method for preparing the above-described semiconductor nanocrystal-siloxane composite resin composition comprising the steps of: a) preparing a composition containing a semiconductor nanocrystal, and at least one silane-based compound selected from the group consisting of the organoalkoxysilane represented by the Chemical Formula 1 and the organosilanediol represented by the Chemical Formula 2; and b) performing a condensation reaction of the composition containing the semiconductor nanocrystal and the silane-based compound while stirring to prepare a semiconductor nanocrystal-siloxane composite resin composition, wherein the step b) includes a step of forming a siloxane resin having a network structure by a condensation reaction of the composition containing the semiconductor nanocrystal and the silane-based compound, and simultaneously dispersing the semiconductor nanocrystal in the siloxane resin and encapsulating the surface of the semiconductor nanocrystal with a siloxane resin.

First, according to the present invention, in the step a), the semiconductor nanocrystal and the silane-based compound are mixed together to produce a composition containing the semiconductor nanocrystal and the silane-based compound. Herein, when the semiconductor nanocrystal is added at the point of time when the condensation reaction is completed, there is a problem that the decrease in the fluorescence intensity in a high temperature environment, and in a high temperature and high humidity environment occurs to a larger extent when the semiconductor nanocrystal is added simultaneously with the formation of a siloxane resin.

Further, in order to perform the step b), the present invention uses sol-gel hydrolytic or non-hydrolytic condensation reaction in the presence of the semiconductor nanocrystals during the preparation of the resin, so that the semiconductor nanocrystals are uniformly dispersed in the siloxane composite resin by physicochemical interaction.

Preferably, the condensation reaction in the step b) may include a hydrolytic condensation reaction of an organoalkoxysilane compound and a water, or a non-hydrolytic condensation reaction of an organoalkoxysilane and an organosilanediol.

More preferably, the hydrolytic condensation reaction may include a hydrolytic condensation reaction of a mixture containing an organoalkoxysilane and water in a molar ratio of 1:0.5 to 4. In addition, the non-hydrolytic condensation reaction may include a non-hydrolytic condensation reaction of a mixture containing an organoalkoxysilane and an organosilanediol in a molar ratio of 1:0.2 to 4.0.

Specifically, the sol-gel condensation reaction of the present invention can include a non-hydrolytic condensation reaction using a mixture of one or more organoalkoxysilanes and an organosilanediol as shown in Reaction Scheme 1 below. In addition, the sol-gel condensation reaction of the present invention can include a hydrolytic condensation reaction of one or more organoalkoxysilanes or one or more organosilanediols as shown in Reaction Schemes 2 to 3 below.

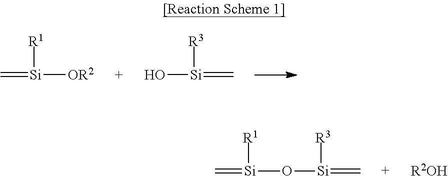

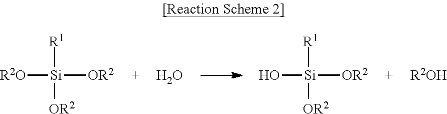

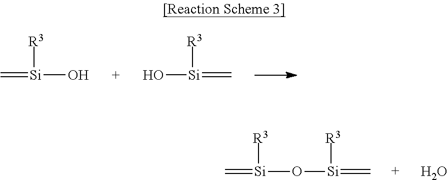

(Herein, R₁ to R₃ are each as defined above)

As can be seen from the above Reaction Schemes 1 to 3, if the hydrolytic or non-hydrolytic sol-gel condensation reaction of an organoalkoxysilane and an organosilanediol proceeds, a dense siloxane network structure having functional groups such as R′ and R″ is formed. The siloxane of the present invention may also include a linear structure.

Further, the present invention is characterized in that, while the siloxane having a network structure is formed, semiconductor nanocrystals are separated from the state of one or more kinds of organoalkoxysilanes, one or more organosilanediols, or a mixture thereof including semiconductor nanocrystals. Thus, the present invention can bind the ligand on the surface of the semiconductor nanocrystal with the functional group of the organoalkoxysilane or the organosilanediol by physicochemical interaction (hydrophobic interaction), and as a result, the above silane-based compound is positioned around the semiconductor nanocrystals by the interaction. Therefore, through such a series of processes, a siloxane composite resin composition in which semiconductor nanocrystals are uniformly dispersed and encapsulated in a siloxane having a network structure is produced (see FIG. 1).

Further, in the present invention, the semiconductor nanocrystals may be used in an amount of 0.01 to 10 parts by weight based on 100 parts by weight of the total siloxane composite resin formed through the condensation reaction. When used for the reaction, the semiconductor nanocrystals may be used in a state in which semiconductor nanocrystals are dispersed in a solvent. The type of the organic solvent used herein is not limited, but chloroform, toluene, hexane and the like can be used.

In addition, in the composition containing the silane-based compound, one or more organoalkoxysilanes, one or more organosilanediols, or a mixture thereof are used, and a mixture can be used by adjusting the proportions thereof.

According to a preferred embodiment, when the non-hydrolytic condensation reaction as shown in Reaction Schemes 1 and 3 is carried out, the silane-based compound may contain an organoalkoxysilane and an organosilanediol in a molar ratio of 1:0.2 to 5, as described above.

According to another preferred embodiment, when the hydrolytic condensation reaction as shown in Reaction Scheme 2 is carried out, the silane-based compound may contain an organoalkoxysilane and water in a molar ratio of 1:0.5 to 5 as described above. In this case, when the molar ratio between the above two substances is less than 1:0.5, the hydrolytic sol-gel condensation reaction does not occur sufficiently and thus the formation of the siloxane structure is very low. When the molar ratio between the above two substances is more than 1:0.5, it is impossible to produce a uniform semiconductor nanocrystal-resin composition and a cured product thereof due to excess water which is not involved in the hydrolysis reaction of the alkoxy group of organoalkoxysilane and water, and the semiconductor nanocrystal may be oxidized by water to deteriorate the intrinsic properties of the semiconductor nanocrystal.

On the other hand, the condensation reaction is preferably carried out by adjusting the reaction temperature, the reaction atmosphere, and the kind and amount of the catalyst.

For example, the condensation reaction may be carried out at a temperature of 0 to 120° C. for 4 to 120 hours. In this case, the condensation reaction is sufficiently carried out by stirring at room temperature for about 4 to 120 hours, but it may be carried out at 0 to 120° C., preferably 40 to 100° C. for 2 to 48 hours, in order to accelerate the reaction rate.

The non-hydrolytic condensation reaction can be carried out in the presence of an acid or base catalyst. Examples of usable catalysts include acid catalysts such as hydrochloric acid, hydrofluoric acid, acetic acid, nitric acid, sulfuric acid, chlorosulfonic acid, pyrophosphoric acid and iodic acid; basic catalysts such as ammonia, potassium hydroxide, sodium hydroxide, barium hydroxide, strontium hydroxide and imidazole; and Amberite IRA-67, IRA-400, and the like, and can be selected and used from the group consisting of these combinations. The amount of the catalyst may be added from 0.0001 to 10 mol % based on 1 mol of the silane-based compound used in the reaction, but the amount thereof is not particularly limited.

Moreover, as can be seen from the Reaction Schemes 1 to 3, when a reaction occurs, alcohols or water as by-products are produced and may be present in the resin, but can be removed by applying the conditions of about 40 to 100° C. under atmospheric pressure and reduced pressure for 30 minutes to 3 hours. In addition, a solvent in which the semiconductor nanocrystals are dispersed can also be removed under the above conditions.

Further, in the case of the present invention, after the step b), the step of adding a curing catalyst to the semiconductor nanocrystal-siloxane composite resin composition can be further included.

Then, the method may further include the step of adding, to the semiconductor nanocrystal-siloxane composite resin composition of the step b), a reactive monomer or oligomer having an epoxy group, an acrylic group, or an oxetane group in an amount of 1 to 50 parts by weight based on 100 parts by weight of the total siloxane composite resin.

Cured Product of Semiconductor Nanocrystal-Siloxane Composite

On the other hand, according to another embodiment of the present invention, there is provided a cured product of a semiconductor nanocrystal-siloxane composite obtained through photocuring or heat curing of the above-described semiconductor nanocrystal-siloxane composite resin composition.

That is, according to the present invention, since the siloxane composite resin encapsulating semiconductor nanocrystals has a curable organic functional group and stably protects semiconductor nanocrystals, it is possible to produce a cured product having excellent bonding force through the ultraviolet curing and/or heat curing steps that are generally well-known in the art.

In one embodiment of the present invention, in order to control the viscosity, free volume and the like of the semiconductor nanocrystal-siloxane composite resin and to facilitate the processability, a reactive monomer or oligomer capable of ultraviolet curing and/or heat curing can be added as described above. The amount of the reactive monomer or oligomer to be added is not particularly limited, but may be added in an amount of about 1 to about 50 parts by weight based on 100 parts by weight of the total siloxane composite resin. The reactive monomer or oligomer may have an epoxy group, an acrylic group, a methacrylic group, or an oxetane group, but the kind thereof may not be particularly limited.

In order to control the secondary performance of the semiconductor nanocrystal-siloxane composite resin, an organic fluorescent substance, an inorganic fluorescent substance, a conjugated polymer, a surfactant, a light diffusing agent, an antioxidant, an active oxygen remover, a silica sol, an oxide, a heat resistant agent, and the like can be added within a range that does not affect the effect of the present invention, but is not limited thereto.

The curing step of the semiconductor nanocrystal-siloxane composite resin composition can be carried out in the presence of a generally-used catalyst. The cured product may include a step of heat treating at a temperature of 200° C. or less, preferably 50° C. to 180° C. or less after curing, but the condition is not limited.

In one embodiment of the present invention, the semiconductor nanocrystal-siloxane composite resin composition can be prepared as a cured product by using various molding steps such as coating, casting, molding, and 3D printing, but the molding method may not be limited. Further, the cured product according to the present invention may include films, flakes, sheets, or encapsulated LED chips.

Further, the present invention can provide a device including a cured product of a semiconductor nanocrystal-siloxane composite.

The device includes a display and a lighting device, but is not particularly limited. That is, the semiconductor nanocrystal-siloxane composite resin composition presented in the present invention and a cured product using the same are applied to both display and lighting devices such as an optical wavelength converter, a laser, a color filter, a solar cell, and a LED device.

As described above, the semiconductor nanocrystal-siloxane composite resin composition according to the present invention contains a siloxane composite resin that achieves uniform dispersion without exchanging the surface ligands of semiconductor nanocrystals. Therefore, there is an advantage that it is possible to avoid degradation of characteristics of the nanocrystals inevitably generated during semiconductor ligand exchange, which is a conventional problem, thereby maintaining uniform dispersion of the semiconductor nanocrystals for a long time and providing excellent storage stability. Further, semiconductor nanocrystals are encapsulated by siloxane having a dense inorganic network structure, and the semiconductor nanocrystals are protected from the external environment (heat and moisture) and fluorescence characteristics are maintained even when exposed to a high temperature and a high temperature and high humidity environment, for a long time, thereby providing high reliability of the application devices.

The effect of the invention will be described in more detail through specific examples of the invention below. However, the following examples are presented for illustrative purposes only, and are not intended to limit the scope of the invention.

As for the semiconductor nanocrystals used in the following examples, Nanodot-HE-620 (trade name, Ecoflux, Korea) which has a Cd-based core-shell structure was used. The semiconductor nanocrystals were dispersed in a chloroform solvent, and added in an amount of 1 part by weight based on 100 parts by weight of the siloxane resin (excluding the weight of the solvent).

### Example 1

Semiconductor nanocrystals and a mixture containing 3-(meth)acryloxypropyltrimethoxysilane and diphenylsilanediol at a molar ratio of 1:1.25 were added to a 250 ml 2-neck flask, to which barium hydroxide was added as a catalyst, and then stirred at 80° C. for 6 hours to perform a non-hydrolytic condensation reaction, thereby preparing the siloxane composite resin composition. At this time, the catalyst was added in an amount of 0.1 mol % based on 1 mol of the total silane-based compound. Through the above process, simultaneously with formation of a siloxane network structure, a resin composition in which semiconductor nanocrystals were dispersed and encapsulated by a siloxane composite resin was produced. Thereafter, 2 parts by weight of 2,2-dimethoxy-2-phenylacetophenone as a photocuring catalyst was added to the resin composition based on 100 parts by weight of the entire siloxane composite resin. The semiconductor nanocrystal-siloxane composite resin composition thus prepared was coated on the PET surface to a thickness of 100 μm and then exposed to an ultraviolet lamp at a wavelength of 365 nm for 3 minutes to prepare a cured product.

### Example 2

Semiconductor nanocrystals and a mixture containing 3-(meth)acryloxypropyltrimethoxysilane and diphenylsilanediol at a molar ratio of 1:1.25 were added to a 250 ml 2-neck flask, to which barium hydroxide was added as a catalyst, and then stirred at 80° C. for 6 hours to perform a non-hydrolytic condensation reaction, thereby preparing the siloxane composite resin composition. At this time, the catalyst was added in an amount of 0.1 mol % based on 1 mol of the total silane-based compound. Through the above process, simultaneously with formation of a siloxane network structure, a resin composition in which semiconductor nanocrystals were dispersed and encapsulated by a siloxane composite resin was produced. Thereafter, 2 parts by weight of benzoyl peroxide as a heat curing catalyst was added to the resin composition based on 100 parts by weight of the entire siloxane composite resin. The siloxane composite resin composition thus prepared was coated on the PET surface to a thickness of 100 μm, and then exposed at 60° C. for 60 minutes to prepare a cured product.

### Example 3

Semiconductor nanocrystals and a mixture containing 3-(meth)acryloxypropyltrimethoxysilane and water at a molar ratio of 1:1.5 were added to a 250 ml 2-neck flask, and then stirred at 80° C. for 6 hours to perform a hydrolytic condensation reaction, thereby preparing the siloxane composite resin composition. Through the above process, simultaneously with formation of a siloxane network structure, a resin composition in which semiconductor nanocrystals were dispersed and encapsulated by a siloxane composite resin was produced. Thereafter, 2 parts by weight of 2,2-dimethoxy-2-phenylacetophenone as a photocuring catalyst was added to the resin composition based on 100 parts by weight of the entire siloxane composite resin. The siloxane composite resin composition thus prepared was coated on the PET surface to a thickness of 100 μm, and then exposed to an ultraviolet lamp at a wavelength of 365 nm for 3 minutes to prepare a cured product.

### Example 4

Semiconductor nanocrystals and a mixture containing 3-(meth)acryloxypropyltrimethoxysilane and water at a molar ratio of 1:1.5 were added to a 250 ml 2-neck flask, and then stirred at 80° C. for 6 hours to perform a hydrolytic condensation reaction, thereby preparing the siloxane composite resin composition. Through the above process, simultaneously with formation of a siloxane network structure, a resin composition in which semiconductor nanocrystals were dispersed and encapsulated by a siloxane composite resin was produced. Thereafter, 2 parts by weight of benzoyl peroxide as a heat curing catalyst was added to the resin composition based on 100 parts by weight of the entire siloxane composite resin. The siloxane composite resin composition thus prepared was coated on the PET surface to a thickness of 100 μm, and then exposed at 60° C. for 60 minutes to prepare a cured product.

### Example 5

Semiconductor nanocrystals and a mixture containing 3-acryloxypropyltrimethoxysilane and diphenylsilanediol at a molar ratio of 1:1.25 were added to a 250 ml 2-neck flask, to which barium hydroxide was added as a catalyst, and then stirred at 80° C. for 6 hours to perform a non-hydrolytic condensation reaction, thereby preparing the siloxane composite resin composition. At this time, the catalyst was added in an amount of 0.1 mol % based on 1 mol of the total silane-based compound. Through the above process, simultaneously with formation of a siloxane network structure, a resin composition in which semiconductor nanocrystals were dispersed and encapsulated by a siloxane composite resin was produced. Thereafter, 2 parts by weight of 2,2-dimethoxy-2-phenylacetophenone as a photocuring catalyst was added to the resin composition based on 100 parts by weight of the entire siloxane composite resin. The siloxane composite resin composition thus prepared was coated on the PET surface to a thickness of 100 μm, and then exposed to an ultraviolet lamp at a wavelength of 365 nm for 3 minutes to prepare a cured product.

### Example 6

Semiconductor nanocrystals and a mixture containing 3-acryloxypropyltrimethoxysilane and diphenylsilanediol at a molar ratio of 1:1.25 were added to a 250 ml 2-neck flask, to which barium hydroxide was added as a catalyst, and then stirred at 80° C. for 6 hours to perform a non-hydrolytic condensation reaction, thereby preparing the siloxane composite resin composition. At this time, the catalyst was added in an amount of 0.1 mol % based on 1 mol of the total silane-based compound. Through the above process, simultaneously with formation of a siloxane network structure, a resin composition in which semiconductor nanocrystals were dispersed and encapsulated by a siloxane composite resin was produced. Thereafter, 2 parts by weight of benzoyl peroxide as a heat curing catalyst was added to the resin composition based on 100 parts by weight of the entire siloxane composite resin. The siloxane composite resin composition thus prepared was coated on the PET surface to a thickness of 100 μm, and then exposed at 60° C. for 60 minutes to prepare a cured product.

### Example 7

Semiconductor nanocrystals and a mixture containing 3-acryloxypropyltrimethoxysilane and water at a molar ratio of 1:1.5 were added to a 250 ml 2-neck flask, and then stirred at 80° C. for 6 hours to perform a hydrolytic condensation reaction, thereby preparing the siloxane composite resin composition. Through the above process, simultaneously with formation of a siloxane network structure, a resin composition in which semiconductor nanocrystals were dispersed and encapsulated by a siloxane composite resin was produced. Thereafter, 2 parts by weight of 2,2-dimethoxy-2-phenylacetophenone as a photocuring catalyst was added to the resin composition based on 100 parts by weight of the entire siloxane composite resin. The siloxane composite resin composition thus prepared was coated on the PET surface to a thickness of 100 μm, and then exposed to an ultraviolet lamp at a wavelength of 365 nm for 3 minutes to prepare a cured product.

### Example 8

Semiconductor nanocrystals and a mixture containing 3-acryloxypropyltrimethoxysilane and water at a molar ratio of 1:1.5 were added to a 250 ml 2-neck flask, and then stirred at 80° C. for 6 hours to perform a hydrolytic condensation reaction, thereby preparing the siloxane composite resin composition. Through the above process, simultaneously with formation of a siloxane network structure, a resin composition in which semiconductor nanocrystals were dispersed and encapsulated by a siloxane composite resin was produced. Thereafter, 2 parts by weight of benzoyl peroxide as a heat curing catalyst was added to the resin composition based on 100 parts by weight of the entire siloxane composite resin. The siloxane composite resin composition thus prepared was coated on the PET surface to a thickness of 100 μm, and then exposed at 60° C. for 60 minutes to prepare a cured product.

### Example 9

Semiconductor nanocrystals and a mixture containing 2-(3,4-epoxycyclohexyl)ethyltrimethoxysilane and diphenylsilanediol at a molar ratio of 1:1.25, were added to a 250 ml 2-neck flask, to which barium hydroxide was added as a catalyst, and the mixture was then stirred at 80° C. for 6 hours to perform a non-hydrolytic condensation reaction, thereby preparing the siloxane composite resin composition. At this time, the catalyst was added in an amount of 0.1 mol % based on 1 mol of the total silane-based compound. Through the above process, simultaneously with formation of a siloxane network structure, a resin composition in which semiconductor nanocrystals were dispersed and encapsulated by a siloxane composite resin was produced. Thereafter, 2 parts by weight of arylsulfonium hexafluoroantimonate salt as a photocuring catalyst was added to the resin composition based on 100 parts by weight of the entire siloxane composite resin. The siloxane composite resin composition thus prepared was coated on the PET surface to a thickness of 100 μm, and then exposed to an ultraviolet lamp at a wavelength of 365 nm for 3 minutes to prepare a cured product.

### Example 10

Semiconductor nanocrystals and a mixture containing 2-(3,4-epoxycyclohexyl)ethyltrimethoxysilane and diphenylsilanediol at a molar ratio of 1:1.25, were added to a 250 ml 2-neck flask, to which barium hydroxide was added as a catalyst, and then stirred at 80° C. for 6 hours to perform a non-hydrolytic condensation reaction, thereby preparing the siloxane composite resin composition. At this time, the catalyst was added in an amount of 0.1 mol % based on 1 mol of the total silane-based compound. Through the above process, simultaneously with formation of a siloxane network structure, a resin composition in which semiconductor nanocrystals were dispersed and encapsulated by a siloxane composite resin was produced. Thereafter, 2 parts by weight of 2-ethyl-4-methylimidazole as a heat curing catalyst was added to the resin composition based on 100 parts by weight of the entire siloxane composite resin. The siloxane composite resin composition thus prepared was coated on the PET surface to a thickness of 100 μm, and then exposed at 60° C. for 60 minutes to prepare a cured product.

### Example 11

Semiconductor nanocrystals and a mixture containing 2-(3,4-epoxycyclohexyl)ethyltrimethoxysilane and water at a molar ratio of 1:1.5 were added to a 250 ml 2-neck flask, and then stirred at 80° C. for 6 hours to perform a hydrolytic condensation reaction, thereby preparing the siloxane composite resin composition. Through the above process, simultaneously with formation of a siloxane network structure, a resin composition in which semiconductor nanocrystals were dispersed and encapsulated by a siloxane composite resin was produced. Thereafter, 2 parts by weight of arylsulfonium hexafluoroantimonate salt as a photocuring catalyst and 20 parts by weight of 3-ethyl-3[[[3-ethyloxetan-3-yl]methoxy]methyl]oxetane as a photopolymerizable reactive monomer were added to the resin composition based on 100 parts by weight of the entire siloxane composite resin. The siloxane composite resin composition thus prepared was coated on the PET surface to a thickness of 100 μm, and then exposed to an ultraviolet lamp at a wavelength of 365 nm for 3 minutes to prepare a cured product.

### Example 12

Semiconductor nanocrystals and a mixture containing 2-(3,4-epoxycyclohexyl)ethyltrimethoxysilane and water at a molar ratio of 1:1.5 were added to a 250 ml 2-neck flask, and then stirred at 80° C. for 6 hours to perform a hydrolytic condensation reaction, thereby preparing the siloxane composite resin composition. Through the above process, simultaneously with formation of a siloxane network structure, a resin composition in which semiconductor nanocrystals were dispersed and encapsulated by a siloxane composite resin was produced. Thereafter, 2 parts by weight of 2-ethyl-4-methylimidazole as a photo curing catalyst and 20 parts by weight of 3-ethyl-3[[[3-ethyloxetan-3-yl]methoxy]methyl]oxetane as a heat polymerizable reactive monomer were added to the resin composition based on 100 parts by weight of the entire siloxane composite resin. The siloxane composite resin composition thus prepared was coated on the PET surface to a thickness of 100 μm, and then exposed at 60° C. for 60 minutes to prepare a cured product.

In order to show the effect of protecting the semiconductor nanocrystals from the external environment by the siloxane structure having a dense network structure which is characteristic of the siloxane composite resin composition and the cured product thereof in which the semiconductor nanocrystals are dispersed according to the present disclosure, the following comparative examples not including the siloxane structure were carried out.

### Comparative Example 1

As the polymer resin, a (meth)acrylic resin product having a bifunctional group (Miramer M244 (trade name), Miwon Chemical, Korea) was used. After adding the semiconductor nanocrystals to the resin and stirring them at 80° C. for 6 hours, the solvent in which the semiconductor nanocrystals were dispersed was removed to produce a resin. Thereafter, 2 parts by weight of 2,2-dimethoxy-2-phenylacetophenone which is a photo-curing catalyst was added to the resin relative to the total polymer resin. The semiconductor nanocrystal-siloxane composite resin composition thus prepared was coated on the PET surface to a thickness of 100 μm, and then exposed to an ultraviolet lamp at a wavelength of 365 nm for 3 minutes to prepare a cured product.

### Comparative Example 2

As the polymer resin, a (meth)acrylic resin product having a bifunctional group (Miramer M244 (trade name), Miwon Chemical, Korea) was used. After adding the semiconductor nanocrystals to the resin and stirring them at 80° C. for 6 hours, the solvent in which the semiconductor nanocrystals were dispersed was removed to produce a resin. Thereafter, 2 parts by weight of benzoyl peroxide as a heat curing catalyst was added to the resin relative to the total polymer resin. The semiconductor nanocrystal-siloxane composite resin composition thus prepared was coated on the PET surface to a thickness of 100 μm, and then exposed at 60° C. for 60 minutes to prepare a cured product.

### Comparative Example 3

As the polymer resin, an acrylic resin product having a bifunctional group (Miramer M244 (trade name), Miwon Chemical, Korea) was used. After adding the semiconductor nanocrystals to the resin and stirring them at 80° C. for 6 hours, the solvent in which the semiconductor nanocrystals were dispersed was removed to produce a resin. Thereafter, 2 parts by weight of 2,2-dimethoxy-2-phenylacetophenone as a photocuring catalyst was added to the resin relative to the total polymer resin. The semiconductor nanocrystal-siloxane composite resin composition thus prepared was coated on the PET surface to a thickness of 100 μm, and then exposed to an ultraviolet lamp at a wavelength of 365 nm for 3 minutes to prepare a cured product.

### Comparative Example 4

As the polymer resin, an acrylic resin product having a bifunctional group (Miramer M244 (trade name), Miwon Chemical, Korea) was used. After adding the semiconductor nanocrystals to the resin and stirring them at 80° C. for 6 hours, the solvent in which the semiconductor nanocrystals were dispersed was removed to produce a resin. Thereafter, 2 parts by weight of benzoyl peroxide as a heat curing catalyst was added to the resin relative to the total polymer resin. The semiconductor nanocrystal-siloxane composite resin composition thus prepared was coated on the PET surface to a thickness of 100 μm, and then exposed at 60° C. for 60 minutes to prepare a cured product.

### Comparative Example 5

As the polymer resin, an epoxy resin product having a bifunctional group (Miramer PF2120C (trade name), Miwon Chemical, Korea) was used. After adding the semiconductor nanocrystals to the resin and stirring them at 80° C. for 6 hours, the solvent in which the semiconductor nanocrystals were dispersed was removed to produce a resin. Thereafter, 2 parts by weight of arylsulfonium hexafluoroantimonate salt as a photocuring catalyst was added to the resin relative to the total polymer resin. The semiconductor nanocrystal-siloxane composite resin composition thus prepared was coated on the PET surface to a thickness of 100 μm, and then exposed to an ultraviolet lamp at a wavelength of 365 nm for 3 minutes to prepare a cured product.

### Comparative Example 6

As the polymer resin, an epoxy resin product having a bifunctional group (Miramer PE2120C (trade name), Miwon Chemical, Korea) was used. After adding the semiconductor nanocrystals to the resin and stirring them at 80° C. for 6 hours, the solvent in which the semiconductor nanocrystals were dispersed was removed to produce a resin. Thereafter, 2 parts by weight of 2-ethyl-4-methylimidazole as a heat curing catalyst was added to the resin relative to the total polymer resin. The semiconductor nanocrystal-siloxane composite resin composition thus prepared was coated on the PET surface to a thickness of 100 μm, and then exposed at 60° C. for 60 minutes to prepare a cured product.

### [Experimental Example 1] Evaluation of Dispersion Stability

After the resin compositions according to Examples 1 to 12 and Comparative Examples 1 to 6 prepared as described above were stored at room temperature for 40 days, the dispersion stability of the semiconductor nanocrystals in the resin composition was confirmed.

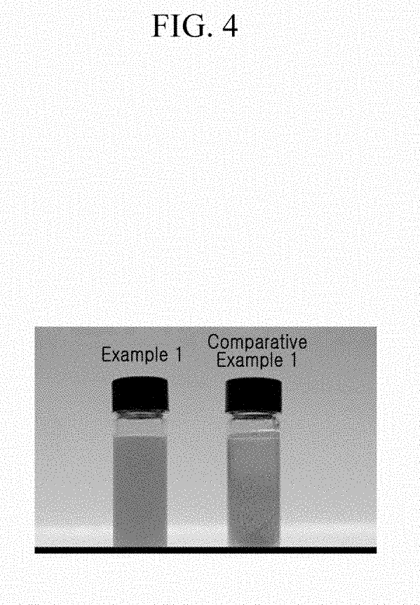

FIG. 4 shows the evaluation results of the dispersion stability of the semiconductor nanocrystal-siloxane composite resin composition of Comparative Example 1 and Example 1 of the present invention.

Referring to FIG. 4, when the semiconductor nanocrystal-siloxane composite resin of Example 1 was stored at room temperature for 40 days, it maintained uniform dispersion without aggregation of the semiconductor nanocrystals. However, under the same environment, the semiconductor nanocrystal polymer composite resin of Comparative Example 1 showed that the semiconductor nanocrystals in the resin were aggregated and precipitated within one day. Thus, it was confirmed that the semiconductor nanocrystal-siloxane composite resin composition according to the present invention exhibited excellent dispersion stability compared with a commercialized polymer resin without organic ligand exchange of a semiconductor nanocrystal and without adding a dispersant.

### [Experimental Example 2] Evaluation of High Temperature and High Humidity Stability (60° C./90% Humidity, 85° C./85% Humidity)

The cured products prepared in Examples 1 to 12 and Comparative Examples 1 to 6 prepared as described above were exposed to the environment of 60° C./90% humidity and 85° C./85% humidity for 40 days, and the change in the fluorescence intensity was measured by using a fluorometric analyzer (DARSA PRO 5100, manufactured by PSI Co., Ltd.).

Table 1 shows the changes in the fluorescence intensity before and after exposure to the high temperature and high humidity environment in the examples and comparative examples.

TABLE 1

| | Change in the fluorescence | Change in the fluorescence |
|---|---|---|
| | intensity after exposure to | intensity after exposure to |
| | 60° C./90% humidity for | 85° C./85% humidity for |
| | 40 days (%) | 40 days (%) |
| Example 1 | 0 | 0 |
| Example 2 | 0 | 0 |
| Example 3 | 0 | 0 |
| Example 4 | 0 | 0 |
| Example 5 | 0 | 0 |
| Example 6 | 0 | 0 |
| Example 7 | 0.5 | 0 |
| Example 8 | 0 | 0 |
| Example 9 | 1.5 | 2.5 |
| Example 10 | 2 | 0.5 |
| Example 11 | 1.5 | 2 |
| Example 12 | 2.5 | 3 |
| Comparative | 18 | 25 |
| Example 1 | | |
| Comparative | 19 | 22 |
| Example 2 | | |
| Comparative | 20 | 28 |
| Example 3 | | |
| Comparative | 25 | 30 |
| Example 4 | | |
| Comparative | 30 | 32 |
| Example 5 | | |
| Comparative | 28 | 35 |
| Example 6 | | |

Referring to Table 1, it can be seen that the fluorescent strength of the cured product of the semiconductor nanocrystal-siloxane composite according to Examples 1 to 12 had a reduction of up to 3%, and fluorescent strength of the cured product of the semiconductor nanocrystal polymer composite of Comparative Examples 1 to 6 had a reduction of up to 35%. As a result, the cured product of the semiconductor nanocrystal-siloxane composite according to the present invention was excellent in fluorescence stability in a high temperature and high humidity environment and thus can be applied to an optical device.

### [Experimental Example 3] Evaluation of High Temperature Stability (60° C., 85° C.)

The cured products prepared in Examples 1 to 12 and Comparative Examples 1 to 6 prepared as described above were exposed to the environment of 60° C. and 85° C. for 40 days, and the change in the fluorescence intensity was measured by using a fluorometric analyzer (DARSA PRO 5100, manufactured by PSI Co., Ltd.).

Table 2 shows the comparison of the changes in the fluorescence intensity before and after exposure to a high temperature environment in the examples and comparative examples.

TABLE 2

| | Change in the fluorescence | Change in the fluorescence |
|---|---|---|
| | intensity after exposure to | intensity after exposure to |
| | 60° C. for 40 days (%) | 85° C. for 40 days (%) |
| Example 1 | 0 | 3 |
| Example 2 | 0 | 2 |
| Example 3 | 0 | 2 |
| Example 4 | 0 | 3 |
| Example 5 | 0 | 4 |
| Example 6 | 0 | 2 |
| Example 7 | 0.5 | 3 |
| Example 8 | 1 | 3 |
| Example 9 | 0.5 | 3 |
| Example 10 | 0 | 3 |
| Example 11 | 1.5 | 20 |
| Example 12 | 0.8 | 23 |
| Comparative | 9 | 33 |
| Example 1 | | |
| Comparative | 7.5 | 30 |
| Example 2 | | |
| Comparative | 8 | 38 |
| Example 3 | | |
| Comparative | 10.5 | 40.5 |
| Example 4 | | |
| Comparative | 13 | 44 |
| Example 5 | | |
| Comparative | 11 | 45 |
| Example 6 | | |

Referring to Table 2, the fluorescence intensity of the cured product of the semiconductor nanocrystal-siloxane composite according to Examples 1 to 10 had a reduction of up to 4%, and the cured product of Examples 11 and 12 in which the reactive monomer was added in an amount of 20 parts by weight relative to the siloxane resin showed about a 20% decrease in the fluorescence intensity in a high temperature environment at 85° C. It is considered that this is attributed to reactive monomers that do not contain a siloxane structure in the composite cured product

However, it can be seen that the fluorescence intensity of the cured product of the semiconductor nanocrystal polymer composite according to Comparative Examples 1 to 6 has a reduction of up to 45%. Accordingly, the cured product prepared through the semiconductor nanocrystal-siloxane composite resin according to the present invention was excellent in the fluorescence stability in a high temperature environment and thus could be applied to an optical device.

From the above Experimental Examples 1 to 3, it was confirmed that the semiconductor nanocrystal-siloxane composite resin composition prepared according to the present invention maintained an uniform and excellent dispersion property for a long time without exchanging the organic ligand of the semiconductor nanocrystal surface and without adding a dispersant. In addition, the cured product obtained by curing with this resin composition maintained the fluorescent properties of the cured semiconductor nanocrystals even after exposure to high temperature environment for a long time, as well as a high temperature and high humidity environment, thereby allowing the reliability of display application devices to which semiconductor nanocrystals are applied, due to a high stability.

1. A semiconductor nanocrystal-siloxane composite resin composition comprising a composite resin in which the surface of the semiconductor nanocrystal is encapsulated by being dispersed and bound by a siloxane composite resin having a network structure,
wherein the siloxane composite resin having a network structure includes a hydrolytic or non-hydrolytic condensation reaction product derived from at least one silane-based compound selected from the group consisting of an organoalkoxysilane and organosilanediol comprising semiconductor nanocrystals

2. The semiconductor nanocrystal-siloxane composite resin composition of claim 1, wherein the organoalkoxysilane is selected from a compound represented by the following Chemical Formula 1 or a mixture of one or more thereof:
R¹ₙSi(OR²)₄₋ₙ [Chemical Formula 1]
wherein, in the above Chemical Formula 1,
each R¹ is independently a (C₁˜C₂₀) alkyl, a (C₃˜C₈) cycloalkyl, a (C₁˜C₂₀) alkyl substituted with a (C₃˜C₈) cycloalkyl, a (C₂˜C₂₀) alkenyl, a (C₂˜C₂₀) alkynyl or a (C₆˜C₂₀)aryl group, wherein the R₁ may have one or more functional groups selected from the group consisting of an acrylic group, a (meth)acryl group, an aryl group, a halogen group, an amino group, a mercapto group, an ether group, an epoxy group, a vinyl group, a hydrogen group, a methyl group, a phenyl group and an isocyanate group,
each R² is independently a linear or branched (C₁˜C₇) alkyl, and
n is an integer of 0 to 3.

3. The semiconductor nanocrystal-siloxane composite resin composition of claim 1 or 2, wherein the organoalkoxysilane may be one or more selected from the group consisting of tetraethoxysilane, tetramethoxysilane, N-(3-acryloxy-2-hydroxypropyl)-3-aminopropyltriethoxysilane, N-3-(acryloxy-2-hydroxypropyl)-3-aminopropyltrimethoxysilne, N-3-(acryloxy-2-hydroxypropyl)-3-aminopropyltripropoxysilne, 3-acryloxypropylmethylbis(trimethoxy)silane, 3-acryloxypropyltrimethoxysilane, 3-acryloxypropyltriethoxysilane, 3-acryloxypropyltripropoxysilane, 3-(meth)acryloxypropyltrimethoxysilane, 3-(meth)acryloxypropyltrimethoxysilane, 3-(meth)acryloxypropyltripropoxysilane, 2-(3,4-epoxycyclohexyl)ethyltrimethoxysilane, 2-(3,4-epoxycyclohexyl)ethyltriethoxysilane, vinyltrimethoxysilane, vinyltriethoxysilane, vinyltripropoxysilane, methyltrimethoxysilane, methyltriethoxysilane, methyldimethoxysilane, methyldiethoxysilane, phenyltrimethoxysilane, phenyltriethoxysilane, diphenyldimethoxysilane, diphenyldiethoxysilane, N-(aminoethyl-3-aminopropyl)trimethoxysilane, N-(2-aminoethyl-3-aminopropyl)triethoxysilane, 3-aminopropyltrimethoxysilane, 3-aminopropyltriethoxysilane, 3-isocyanatopropyltriethoxysilane, heptadecafluorodecyltrimethoxysilane, chloropropyltrimethoxysilane, and chloropropyltriethoxysilane.

4. The semiconductor nanocrystal-siloxane composite resin composition of claim 1, wherein the organosilanediol is selected from a compound represented by the following Chemical Formula 2 or a mixture of one or more thereof:
R³ₘR⁴_{K}Si(OH)₄₋ₘ₋ₖ [Chemical Formula 2]
wherein, in the above Chemical Formula 2,
R³ and R⁴ are each independently or simultaneously a (C₁˜C₂₀) alkyl, a (C₃˜C₈) cycloalkyl, a (C₁˜C₂₀) alkyl substituted with a (C₃˜C₈) cycloalkyl, a (C₂˜C₂₀) alkenyl, a (C₂˜C₂₀) alkynyl or a (C₆˜C₂₀)aryl group, wherein the R³ and R⁴ may have one or more functional groups selected from the group consisting of an acrylic group, a methacryl group, an aryl group, a halogen group, an amino group, a mercapto group, an ether group, a (C₁˜C₂₀) alkoxy group, a sulfone group, a nitro group, a hydroxy group, a cyclobutene group, a carbonyl group, a carboxyl group, an alkyd group, a urethane group, a vinyl group, a nitrile group, an epoxy group, an oxetane group and a phenyl group, and
m and k are each an integer of 0 to 3.

5. The semiconductor nanocrystal-siloxane composite resin composition of claim 1, wherein the organosilanediol is selected from the group consisting of diphenylsilanediol, diisobutylsilanediol, and mixtures thereof.

6. The semiconductor nanocrystal-siloxane composite resin composition according to claim 1, wherein
the semiconductor nanocrystals have a metal-based core-shell structure and includes one or more ligands on the surface.

7. The semiconductor nanocrystal-siloxane composite resin composition of claim 1, wherein
the siloxane composite resin composition may further contain a reactive monomer or oligomer having an epoxy group, an acrylic group or an oxetane group in an amount of 1 to 50 parts by weight based on 100 parts by weight of the total siloxane composite resin.

8. A method for preparing the semiconductor nanocrystal-siloxane composite resin composition of claim 1 comprising the steps of:
a) preparing a composition containing a semiconductor nanocrystal, and at least one silane-based compound selected from the group consisting of the organoalkoxysilane represented by the following Chemical Formula 1 and the organosilanediol represented by the following Chemical Formula 2; and
b) performing a condensation reaction of the composition containing the semiconductor nanocrystal and the silane-based compound while stirring to prepare a semiconductor nanocrystal-siloxane composite resin composition,
wherein the step b) includes a step of forming a siloxane resin having a network structure by a condensation reaction of the composition containing the semiconductor nanocrystal and the silane-based compound, and simultaneously dispersing the semiconductor nanocrystals in the siloxane resin and encapsulating the surface of the semiconductor nanocrystals with a siloxane resin.
R¹ₙSi(OR²)₄₋ₙ [Chemical Formula 1]
wherein, in the above Chemical Formula 1,
each R¹ is independently a (C₁˜C₂₀) alkyl, a (C₃˜C₈) cycloalkyl, a (C₁˜C₂₀) alkyl substituted with a (C₃˜C₈) cycloalkyl, a (C₂˜C₂₀) alkenyl, a (C₂˜C₂₀) alkynyl or a (C₆˜C₂₀)aryl group, wherein the R₁ may have one or more functional groups selected from the group consisting of an acrylic group, a (meth)acryl group, an aryl group, a halogen group, an amino group, a mercapto group, an ether group, an epoxy group, a vinyl group, a hydrogen group, a methyl group, a phenyl group and an isocyanate group,
each R² is independently a linear or branched (C₁˜C₇) alkyl, and
n is an integer of 0 to 3.
R³ₘR⁴_{K}Si(OH)₄₋ₘ₋ₖ [Chemical Formula 2]
in the above formula 2,
R³ and R⁴ are each independently or simultaneously a (C₁˜C₂₀) alkyl, a (C₃˜C₈) cycloalkyl, a (C₁˜C₂₀) alkyl substituted with a (C₃˜C₈) cycloalkyl, a (C₂˜C₂₀) alkenyl, a (C₂˜C₂₀) alkynyl or a (C₆˜C₂₀)aryl group, wherein the R³ and R⁴ may have one or more functional groups selected from the group consisting of an acrylic group, a methacryl group, an aryl group, a halogen group, an amino group, a mercapto group, an ether group, a (C₁˜C₂₀) alkoxy group, a sulfone group, a nitro group, a hydroxy group, a cyclobutene group, a carbonyl group, a carboxyl group, an alkyd group, a urethane group, a vinyl group, a nitrile group, an epoxy group, an oxetane group and a phenyl group, and
m and k are each an integer of 0 to 3.

9. The method for preparing the semiconductor nanocrystal-siloxane composite resin composition of claim 8, wherein the semiconductor nanocrystals is used in an amount of 0.01 to 10 parts by weight based on 100 parts by weight of the total siloxane composite resin formed through a condensation reaction.

10. The method for preparing the semiconductor nanocrystal-siloxane composite resin composition of claim 8, wherein the condensation reaction in the step b) includes a hydrolytic condensation reaction or a non-hydrolytic condensation reaction.

11. The method for preparing the semiconductor nanocrystal-siloxane composite resin composition of claim 10, wherein the hydrolytic condensation reaction may include a hydrolytic condensation reaction of a mixture containing an organoalkoxysilane and water in a molar ratio of 1:0.5 to 5.

12. The method for preparing the semiconductor nanocrystal-siloxane composite resin composition of claim 10 wherein the non-hydrolytic condensation reaction includes a non-hydrolytic condensation reaction of a mixture containing an organoalkoxysilane and an organosilanediol in a molar ratio of 1:0.2 to 5.0.

13. The method for preparing the semiconductor nanocrystal-siloxane composite resin composition of claim 8 wherein, after the step b), the method further includes the step of adding a curing catalyst to the semiconductor nanocrystal-siloxane composite resin composition.

14. The method for preparing the semiconductor nanocrystal-siloxane composite resin composition of claim 8 or 13, wherein the method further includes the step of adding, to the semiconductor nanocrystal-siloxane composite resin composition of the step b), a reactive monomer or oligomer having an epoxy group, an acrylic group, or an oxetane group in an amount of 1 to 50 parts by weight based on 100 parts by weight of the entire siloxane composite resin.

15. A cured product of the semiconductor nanocrystal-siloxane composite resin composition of claim 1, obtained through photocuring or heat curing.

16. The cured product of the semiconductor nanocrystal-siloxane composite resin composition of claim 15, wherein the cured product includes films, flakes, sheets or encapsulated LED chips.

17. A device including a cured product of a semiconductor nanocrystal-siloxane composite of claim 15.
